(19) United States
(12) Patent Application Publication
(10) Pub. No.: US 2020/0039526 A1
(43) Pub. Date: Feb. 6, 2020

(54) VOLUME CONTROL SYSTEM FOR VEHICLE

(71) Applicant: ZF ACTIVE SAFETY AND ELECTRONICS US LLC, Livonia, MI (US)

(72) Inventor: YASHANSHU JAIN, Ann Arbor, MI (US)

(21) Appl. No.: 16/527,453

(22) Filed: Jul. 31, 2019

Related U.S. Application Data
(60) Provisional application No. 62/713,795, filed on Aug. 2, 2018.

(51) Int. Cl. B60W 50/00; H03G 3/02; B60Q 5/00; G08G 1/16

(52) U.S. Cl. CPC B60W 50/0098; G08G 1/166; B60Q 5/00; H03G 3/02

(57) ABSTRACT

A volume control system for a vehicle includes at least one of a turn signal indicator and a reverse indicator. A media device outputs audio within the vehicle. A volume control device is associated with the media device. A controller is connected to the volume control device and the at least one of the turn signal and the reverse indicator. The controller detects a volume level of the media device and operates the volume control device to reduce the detected volume level in response to receiving a signal from the at least one of the turn signal indicator or the reverse indicator.

### RELATED APPLICATIONS

This application claims the benefit of U.S. Provisional Application Ser. No. 62/713,795, filed Aug. 2, 2018, the entirety of which is incorporated by reference herein.

### TECHNICAL FIELD

The present invention relates generally to vehicle systems and, in particular, relates to a system for controlling the volume inside a vehicle based on vehicle maneuvers.

### SUMMARY

In one example, a volume control system for a vehicle includes at least one of a turn signal indicator and a reverse indicator. A media device outputs audio within the vehicle. A volume control device is associated with the media device. A controller is connected to the volume control device and the at least one of the turn signal and the reverse indicator. The controller detects a volume level of the media device and operates the volume control device to reduce the detected volume level in response to receiving a signal from the at least one of the turn signal indicator and the reverse indicator.

In another aspect, a method for controlling volume within a vehicle includes detecting a volume level of a media device outputting audio within the vehicle. A signal is received from at least one of a turn signal indicator and a reverse indicator. A volume control device associated with the media device is operated to reduce the detected volume level in response to receiving the signal.

Other objects and advantages and a fuller understanding of the invention will be had from the following detailed description and the accompanying drawings.

### BRIEF DESCRIPTION OF THE DRAWINGS

FIG. 1 is a schematic illustration of a forward moving vehicle including an example volume control system in accordance with the present invention.

FIG. 2 is a block diagram illustration of the volume control system of FIG. 1.

FIG. 3 is a schematic illustration of a reverse moving vehicle including the volume control system.

FIG. 4 is a graph illustrating control of the volume over time.

FIG. 5 is a flow chart illustrating operation of the volume control system.

### DETAILED DESCRIPTION

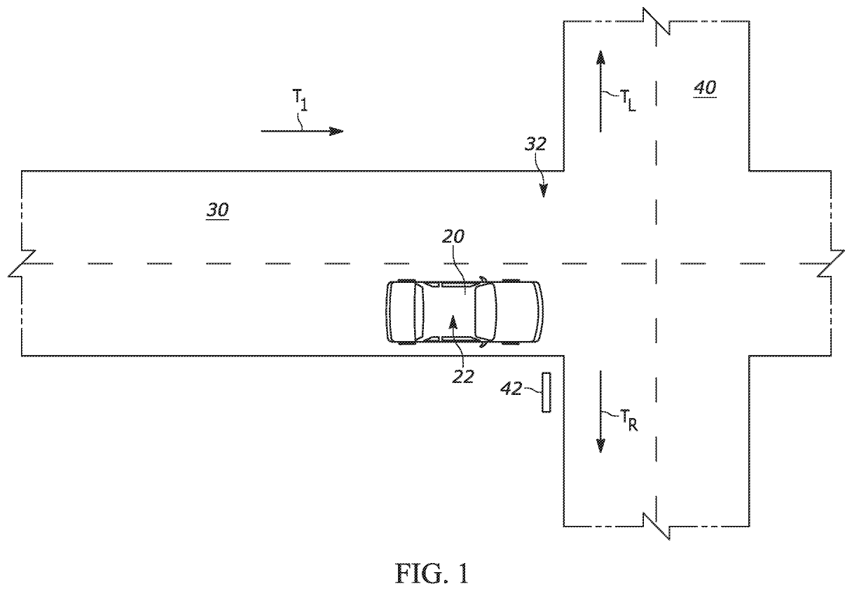

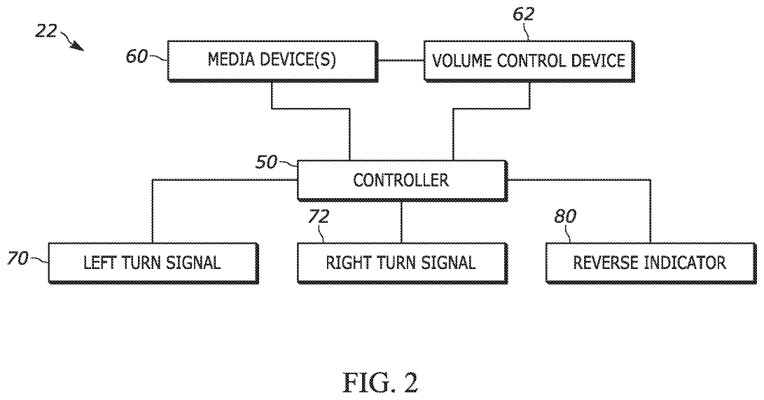

The present invention relates generally to vehicle systems and, in particular, relates to a system for controlling the volume inside a vehicle based on vehicle maneuvers. FIGS. 1-2 illustrate a vehicle 20 traveling along a first roadway 30 and including an example volume control system 22 in accordance with the present invention. As shown in FIG. 1, the vehicle 20 travels in a first direction T₁ along the roadway 30. The first roadway 30 periodically encounters intersections 32, such as with other roadways, driveways, and parking lots. In the example shown in FIG. 1, the first roadway 30 encounters a second roadway 40 at an intersection 32. That said, the control system 22 described herein can adjust the volume within the vehicle 20 based on what the vehicle does at the intersection 32.

Referring to FIG. 2, the control system 22 includes a controller 50 electrically or wirelessly connected to various vehicle components. In one example, the controller 50 is electrically or wirelessly connected to turn signal indicators, namely, a left turn signal 70 and a right turn signal 72. The controller 50 is also electrically or wirelessly connected to one or more media devices 60. A volume control device 62 is associated therewith and connected to the controller 50. The media devices 60 can include one or more media components, such as a radio, television, MP3 player, CD player or any device capable of outputting audio within/into the vehicle. The volume level of the audio produced within the vehicle by the media devices 60 is quantified in decibels (dB).

The volume control device 62 can control the volume level of each media device 60 independently or simultaneously. Consequently, adjusting the volume control device 62 adjusts the dB level within the vehicle 20. The controller 50 continuously detects or measures the volume level of the media device(s) 60 within the vehicle 20 while the vehicle is in operation. The detection can rely on the volume control device 62 or a separate sensor within the vehicle 20 (not shown). For purposes of illustration only, the control system 22 includes a single media device 60.

The controller 50 is also electrically or wirelessly connected to a reverse indicator 80 that indicates when the vehicle 20 is placed in a reverse mode. The reverse indicator 80 can be connected to the vehicle shifter (not shown) or be actuated when the controller 50 places/operates the vehicle 20 in reverse mode (in an autonomous vehicle). In any case, the reverse indicator 80 sends a signal to the controller 50 when/so long as the vehicle 20 is operating in reverse mode.

Referring back to FIG. 1, the vehicle 20 is presented with several options when approaching the intersection 32. To this end, the intersection 32 can include a stop sign 42 or traffic light (not shown) positioned along the first roadway 30. The vehicle 20 can reach the intersection 32, stop at the stop sign 42, and continue moving in the direction T₁ to pass over the second roadway 40. This allows the vehicle 20 to continue movement along the first roadway 30. In this scenario, the volume control system 22 does not alter the volume of the media device 60.

On the other hand, the volume control system 22 alters the volume level of the media device 60 when the vehicle turns onto the second roadway 40. To this end, when it is desirable to turn the vehicle 20 onto the second roadway 40 (or into the driveway, parking lot, etc.) the appropriate turn signal 70 or 72 is actuated before/when the vehicle 20 reaches the stop sign 42. It will be appreciated that this actuation can be accomplished by the operator of the vehicle 20 or autonomously (by the controller 50 in an autonomous vehicle). In any case, the controller 50 receives a signal from one of the turn signals 70 or 72 when/while the turn signal is actuated.

The left turn signal 70 is actuated if it is desirable to turn onto the second roadway 40 to travel in the direction T_{L}. The actuated left turn signal 70 sends a signal to the controller 50 indicative of a left turn until the turn signal deactivates, e.g., by the operator or automatically when a turn is completed. The controller 50, in turn, monitors the duration of the signal from the onset of the left turn signal 70 actuation or from the time at which the signal is received.

If the detected volume level within the vehicle 20 is at or below a threshold amount, e.g., about 95 dB, when the signal is received the controller 50 takes no action. If, however, the detected volume level exceeds the threshold amount, the controller 50 then examines the signal from the left turn signal 70. If the signal duration is less than a predetermined amount, no action is taken by the controller 50 regarding the volume level. If, however, the signal duration is at or greater than the predetermined amount, the controller 50 operates the volume control device 62 to reduce the volume level of the media device 60 until the volume level reaches the threshold amount. This change in volume level can be done gradually and/or continuously.

The volume level of the media device 60 is kept at the threshold amount as long as the left turn signal 70 is actuated. Once the left turn is completed or the left turn signal 70 otherwise deactivated, the controller 50 gradually increases the volume level of the media device 60 until the volume level returns to the detected volume level.

The right turn signal 70 is actuated if it is desirable to turn onto the second roadway 40 to travel in the direction T_{R}. The actuated right turn signal 72 sends a signal to the controller 50 indicative of a right turn until the turn signal deactivates, e.g., by the operator or automatically when a turn is completed. The controller 50, in turn, monitors the duration of the signal from the onset of the right turn signal 70 actuation or from the time at which the signal is received.

If the detected volume level within the vehicle 20 is at or below the threshold amount, no action is taken by the controller 50. If, however, the detected volume level exceeds the threshold amount, the controller 50 then examines the signal from the right turn signal 72. If the signal duration is less than a predetermined amount when the signal is received, the controller 50 takes no action regarding the volume level. If, however, the signal duration is at or greater than the predetermined amount, the controller 50 operates the volume control device 62 to reduce the volume level of the media device 60 until the volume level reaches the threshold amount. This change in volume level can be done gradually and/or continuously.

The volume level of the media device 60 is kept at the threshold amount as long as the right turn signal 72 is actuated. Once the right turn is completed or the right turn signal 72 otherwise deactivated, the controller 50 gradually increases the volume level of the media device 60 until the volume level returns to the detected volume level.

It will be appreciated that the control system 22 of the present invention can also be utilized when the left or right turn signals 70, 72 are actuated in order to use an on-ramp or off-ramp of a highway or change lanes on the first roadway 30 (not shown). In each case, the controller 50 behaves in the same manner to operate the volume control device 62 as previously described with respect to making left or right turns at the intersection 32. Other scenarios in which the control system 22 operates in response to one of the turn signals 70 or 72 being actuated are contemplated.

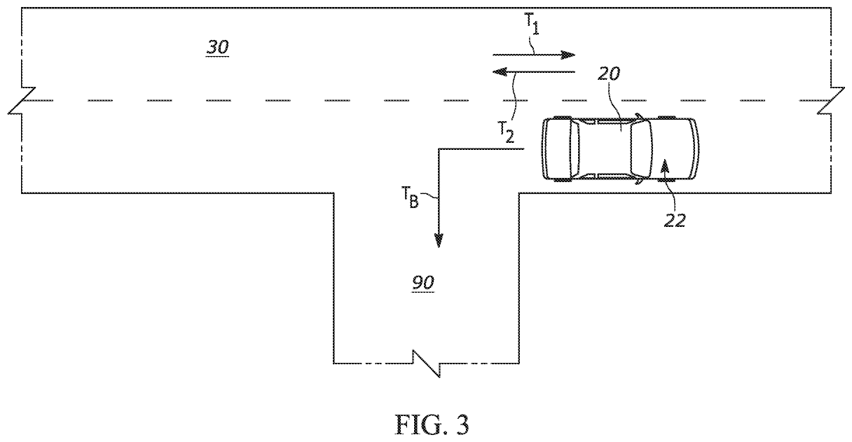

In another example shown in FIG. 3, it may be desirable for the vehicle 20 to operate in reverse in order to parallel park or maneuver around other vehicles (not shown) parked in front of the vehicle 20. In this situation, the vehicle 20 is placed in a reverse mode (either by the operator or autonomously) such that the vehicle can travel in the direction T₂ along the first roadway 30 opposite the direction of travel T₁.

When this occurs, the reverse indicator 80 sends a signal to the controller 50 indicative of operating the vehicle 20 in reverse until the vehicle is placed in the forward operator mode or parked, e.g., by the operator or automatically in autonomous mode.

If the detected volume level within the vehicle 20 is at or below the threshold amount, the controller 50 takes no action. If, however, the detected volume level exceeds the threshold amount, the controller 50 immediately operates the volume control device 62 to reduce the volume level of the media device 60 until the volume level reaches the threshold amount. In other words—unlike when the left and right turn signals 70, 72 are actuated—the controller 50 does not wait for the reverse indicator 80 signal to be detected for a predetermined time before adjusting the volume level. That said, the change in volume level can be done gradually and/or continuously.

The volume level of the media device 60 is kept at the threshold amount as long as the reverse indicator 80 is actuated. Once the reverse driving maneuver is completed or the reverse indicator 80 otherwise deactivated, the controller 50 gradually increases the volume level of the media device 60 until the volume level returns to the detected volume level.

It may also be desirable for the vehicle 20 to operate in reverse and make a turn in order to back into a driveway 90 extending transverse to the first roadway 30 in the manner T_{B} (FIG. 3). In this situation, the vehicle 20 is placed in a reverse mode (either by the operator or autonomously) such that the vehicle can travel in the direction T₂ along the first roadway 30 opposite the direction of travel T₁. The right turn signal 72 is actuated to indicate a desire to turn the vehicle 20 rightward (as viewed from traffic behind the vehicle) into the driveway 90.

When this occurs, both the reverse indicator 80 and the right turn signal 72 send a signal to the controller 50, which collectively indicate operating the vehicle 20 in reverse with a right turn. The signals are sent to the controller 50 until the vehicle is both placed in the forward operator mode or parked, e.g., by the operator or automatically in autonomous mode, and the right turn signal 72 deactivated.

If the detected volume level within the vehicle 20 is at or below the threshold amount, the controller 50 takes no action. If, however, the detected volume level exceeds the threshold amount, the controller 50 immediately operates the volume control device 62 to reduce the volume level of the media device 60 until the volume level reaches the threshold amount. In other words, when the controller 50 receives signals from both the reverse indicator 80 and the right turn signal 70, the controller does not wait a predetermined time before adjusting the volume level. That said, the change in volume level can be done gradually and/or continuously.

The volume level of the media device 60 is kept at the threshold amount as long as either the reverse indicator 80 or the right turn signal 72 is actuated. Once both the reverse driving maneuver and the right turn are completed, the controller 50 gradually increases the volume level of the media device 60 until the volume level returns to the detected volume level.

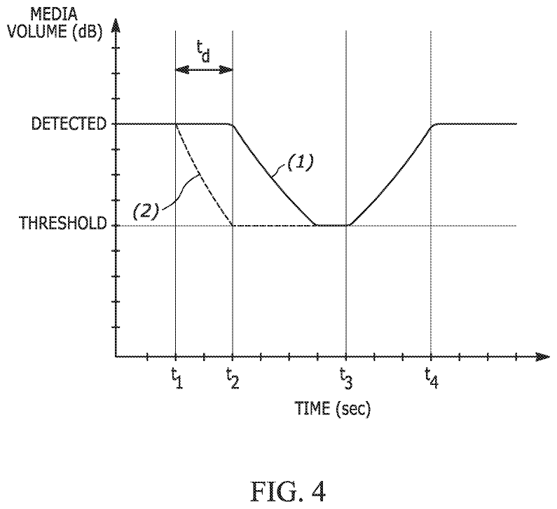

FIG. 4 graphically illustrates operation of the controller in the situations shown in FIG. 1 and FIG. 3. In both cases, at time t₁, the controller receives a signal indicative of a vehicle maneuver, e.g., a left turn signal 70 actuation, a right turn signal 72 actuation or a reverse indicator 80 actuation. Prior to time t₁, the controller 50 has already determined that the detected volume level within the vehicle 20 from the media device 60 is above the threshold amount.

When the vehicle maneuver signal is indicative of a vehicle 20 turn—and after the controller 50 receives the signal for a predetermined time td after the time t₁—the controller 50 operates the volume control device 62 to gradually reduce the volume level of the media device 60 to the threshold value. This change in volume level is shown at (1) in FIG. 4.

At time t3, the controller 50 determines that neither turn signal 70, 72 is actuated. In response thereto, the controller 50 operates the volume control device 62 to gradually increase the volume level of the media device 60 back to the detected volume level at time t4.

When the vehicle maneuver signal at time t₁ is indicative of the vehicle 20 being placed in reverse mode, the controller 50 immediately operates the volume control device 62 to gradually reduce the volume level of the media device 60 to the threshold value. This change in volume level is shown at (2) in FIG. 4.

At time t3, the controller 50 determines that the vehicle 20 is no longer in reverse mode. In response thereto, the controller 50 operates the volume control device 62 to gradually increase the volume level of the media device 60 back to the detected volume level at time t4.

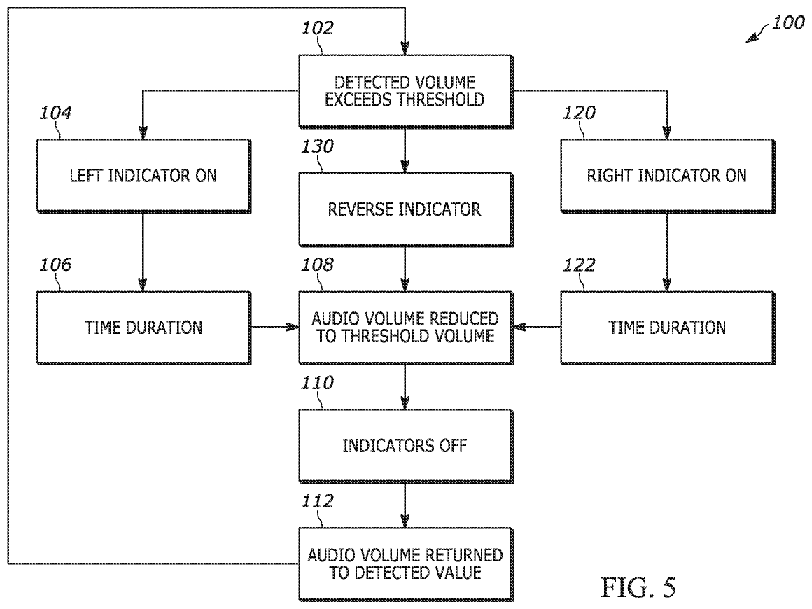

A flow chart 100 depicting operation of the controller 50 is shown in FIG. 5. At step 102, the controller 50 detects the volume level of the media device 60 and determines that the volume level exceeds the threshold amount. At step 104, the controller 50 receives a signal from the left turn signal 70. At step 106, the controller 50 determines that the signal has been received for a predetermined time duration. At step 108, the controller 50 operates the volume control device 62 to reduce the volume level of the media device 60 to the threshold amount. At step 110, the controller 50 determines that the left turn signal 70 is deactivated. At step 112, the controller 50 operates the volume control device 62 to return the volume level of the media device 60 to the detected volume level. The controller 50 then returns to monitoring/detecting the volume level of the media device 60.

At step 120, the controller 50 receives a signal from the right turn signal 72. At step 122, the controller 50 determines that the signal has been received for a predetermined time duration. At step 108, the controller 50 operates the volume control device 62 to reduce the volume level of the media device 60 to the threshold amount. At step 110, the controller 50 determines that the right turn signal 72 is deactivated. At step 112, the controller 50 operates the volume control device 62 to return the volume level of the media device 60 to the detected volume level. The controller 50 then returns to monitoring/detecting the volume level of the media device 60.

At step 130, the controller 50 receives a signal from the reverse actuator 80. At step 108, the controller 50 operates the volume control device 62 to reduce the volume level of the media device 60 to the threshold amount. At step 110, the controller 50 determines that the reverse indicator 80 is deactivated. At step 112, the controller 50 operates the volume control device 62 to return the volume level of the media device 60 to the detected volume level. The controller 50 then returns to monitoring/detecting the volume level of the media device 60.

The control system and method shown and described herein are advantageous for helping to increase the attentiveness of the driver/operator. Elevated volume levels within the vehicle due to, for example, loud music can reduce the attentiveness of the driver/operator. This can hinder driver/operator response times to certain events, e.g., braking, vehicle impacts or collisions. By reducing the volume level within the vehicle during certain vehicle maneuvers, the driver/operator can be more aware of the environment surrounding the vehicle during the maneuver.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A volume control system for a vehicle, comprising:
at least one of a turn signal indicator and a reverse indicator;
a media device outputting audio within the vehicle;
a volume control device associated with the media device; and
a controller connected to the volume control device and the at least one of the turn signal and the reverse indicator, the controller detecting a volume level of the media device and operating the volume control device to reduce the detected volume level in response to receiving a signal from the at least one of the turn signal indicator and the reverse indicator.

2. The volume control system recited in claim 1, wherein the controller operates the volume control device to reduce the detected volume level of the media device if the detected volume level is above a threshold amount when the signal is received.

3. The volume control system recited in claim 2, wherein the controller reduces the detected volume level of the media device to the threshold amount after the controller receives the signal for a predetermined time duration.

4. The volume control system in claim 3, wherein the controller returns the volume level of the media device to the detected volume level once the signal is no longer received by the controller.

5. The volume control system recited in claim 1, wherein the turn signal indicator comprises a left turn signal.

6. The volume control system recited in claim 1, wherein the turn signal indicator comprises a right turn signal.

7. The volume control system recited in claim 1, wherein the media device comprises multiple media components each outputting audio within the vehicle.

8. The volume control system recited in claim 1, wherein the at least one of the turn signal indicator and the reverse indicator includes both the turn signal indicator and the reverse indicator, the controller operating the volume control device to reduce the detected volume level in response to receiving a signal from the turn signal indicator and the reverse indicator.

9. A method for controlling volume within a vehicle, comprising:
detecting a volume level of a media device outputting audio within the vehicle;
receiving a signal from at least one of a turn signal indicator and a reverse indicator; and
operating a volume control device associated with the media device to reduce the detected volume level in response to receiving the signal.

10. The method recited in claim 9, wherein the volume control device is operated if the detected volume level is above a threshold amount when the signal is received.

11. The method recited in claim 9 further comprising returning the volume level of the media device to the detected volume level once the signal is no longer received by the controller.

12. The method recited in claim 9, wherein the volume control device is operated if the detected volume level is above a threshold amount when the signal is received for a predetermined time duration.

13. The method recited in claim 9, wherein the turn signal indicator comprises a left turn signal.

14. The method recited in claim 9, wherein the turn signal indicator comprises a right turn signal.

15. The method recited in claim 9, wherein the media device comprises multiple media components each outputting audio within the vehicle.

16. The method recited in claim 9, wherein the at least one of the turn signal indicator and the reverse indicator includes both the turn signal indicator and the reverse indicator, the controller operating the volume control device to reduce the detected volume level in response to receiving a signal from the turn signal indicator and the reverse indicator.
